(19) United States
(12) Patent Application Publication
(10) Pub. No.: US 2004/0187912 A1
(43) Pub. Date: Sep. 30, 2004

(54) Multijunction solar cell and current-matching method

(75) Inventors: Tatsuya Takamoto, Ikoma-gun (JP); Takaaki Agui, Yamatokoriyama-shi (JP)

Correspondence Address: NIXON & VANDERHYE, PC, 1100 N GLEBE ROAD, 8TH FLOOR, ARLINGTON, VA, 22201-4714, US

(73) Assignee: Sharp Kabushiki Kaisha, Osaka (JP)

(21) Appl. No.: 10/788,320

(22) Filed: Mar. 1, 2004

(30) Foreign Application Priority Data
Mar. 26, 2003 (JP) 2003-085379

(51) Int. Cl. H01L 31/00

(52) U.S. Cl. 136/255; 136/249; 136/262

(57) ABSTRACT

In an InGaP/InGaAs/Ge triple-junction solar cell, efficiency of a multijunction solar cell is improved by adjusting a ratio of an Al composition in an (Al)InGaP cell. According to a current-matching method in a multijunction solar cell, the ratio of the Al composition in an AlInGaP material for a top cell is adjusted in order to achieve matching between photocurrents generated in the top cell and a middle cell in the multijunction solar cell. Here, the multijunction solar cell uses as the top cell a solar cell-formed with the AlInGaP material and having a PN junction, uses as a middle cell a solar cell lattice-matched to the top cell, formed with an (In)GaAs(N) material and having a PN junction, and uses as a bottom cell a solar cell lattice-matched to the middle cell, formed with a Ge material and having a PN junction.

This nonprovisional application is based on Japanese Patent Application No. 2003-085379 filed with the Japan Patent Office on Mar. 26, 2003, the entire contents of which are hereby incorporated by reference.

### BACKGROUND OF THE INVENTION

1. Field of the Invention

The present invention relates to a multijunction solar cell of high efficiency, and more particularly to a method of improving efficiency of a multijunction solar cell adapted to a various types of sunlight such as terrestrial solar spectrum, condensed sunlight spectrum and space solar spectrum, as well as to a solar cell of high efficiency. In addition, the present invention relates to a method of suppressing deterioration of a solar cell due to radiation in space, and a multijunction solar cell less prone to deterioration due to the radiation.

2. Description of the Background Art

Recently, multijunction solar cells using as a main material a semiconductor composed of group III-V compound such as GaAs have increasingly been employed as a space solar cell used as a power source for space equipment such as an artificial satellite. As these cells are expected to achieve photoelectric conversion efficiency higher than that of an Si solar cell, which has conventionally been used widely as the space solar cell, they are suitable for a small-sized satellite or a high-power satellite of which design has been difficult with the Si cell.

Among such solar cells, the solar cell currently attaining highest conversion efficiency regardless of its terrestrial or space application is an InGaP/InGaAs/Ge triple-junction multijunction solar cell. One exemplary method of improving conversion efficiency of the multijunction solar cell is to match photocurrents in the cells constituting the multijunction solar cell. Here, as three cells, that is, an InGaP cell, an InGaAs cell and a Ge cell, are connected in series, a value for a short-circuit current in the multijunction solar cell is restricted to a lowest photocurrent value of those cells. In order to obtain the highest short-circuit current value, it is necessary to absorb sunlight in a manner well-balanced among cells and to equalize values of the generated photocurrents among the cells. Namely, a method of matching currents is necessary.

Conventionally, in order to achieve current-matching, a method of adjusting a quantity of light absorbed by the InGaAs cell in a lower portion by reducing a thickness of the InGaP cell in an upper portion so as to increase the quantify of light transmitting therethrough has been employed. For example, U.S. Pat. No. 5,223,043 discloses a dual-junction solar cell, in which GaInP is used as a material for a top cell serving as a first solar cell formed on the sunlight incident surface and GaAs is used as a material for a bottom cell serving as a second solar cell formed under the top cell. FIG. 1 shows a basic structure of such cells. Conversion efficiency achieved by these conventional multijunction cells in a characteristic test using a light source simulating the solar spectrum in the space is approximately 26% in laboratory and approximately 22% in an industrial product respectively.

A thickness of an InGaP cell in a multijunction solar cell for terrestrial use has been set to approximately 0.6 μm with respect to the terrestrial sunlight having AM 1.5 spectrum. On the other hand, a thickness of an InGaP cell in a multijunction solar cell for space use has been set to approximately 0.4 μm with respect to the space sunlight having AM 0 spectrum. In addition, in order to improve resistance to radiation in space, the thickness of the InGaP cell has been set to as small as 0.3 μm. With regard to an influence by radiation in space, the degree of lowering in the photocurrent is not significant in an InGaP-based material, whereas it is large in an InGaAs material. Therefore, in order to suppress lowering in the short-circuit current value in space, the thickness of the InGaP cell has been made sufficiently small so as to sufficiently increase the quantity of light transmitting to the InGaAs cell. As described above, in the conventional art, a method of adjusting a film thickness of the cell has mainly been adopted in order to improve the conversion efficiency.

In the InGaP/InGaAs/Ge triple-junction cell having a pn junction formed also in a Ge substrate, a photocurrent generated in a Ge cell is sufficiently larger than that in other sub cells. Therefore, it is not necessary to adjust the quantity of light transmitting to the Ge cell.

With the conventional current-matching method as described above, current-matching has been achieved without difficulty and high short-circuit current can be obtained. On the other hand, significant change in a voltage generated in the sub cell does not take place, and accordingly, improvement in an open-circuit voltage in a multijunction solar cell has not sufficiently been attained.

### SUMMARY OF THE INVENTION

The present invention was made to solve the above-described problems of the conventional art. An object of the present invention is to decrease an absorption edge wavelength by adding Al to the top cell so as to increase the Al composition ratio in the (Al)InGaP cell, and to obtain a sufficient short-circuit current by adjusting a quantity of light transmitting to the InGaAs cell in a lower portion so as to achieve current-matching in an InGaP/InGaAs/Ge triple-junction solar cell, for example. In addition, another object of the present invention is to raise a voltage by increasing band gap in the (Al)InGaP cell as well as to improve efficiency of the multijunction solar cell.

According to a current-matching method in a multijunction solar cell according to one aspect of the present invention, a ratio of an Al composition in an AlInGaP material for a top cell is adjusted in order to achieve matching between photocurrents generated in the top cell and a bottom cell in a multijunction solar cell. The multijunction solar cell uses as the top cell a solar cell formed with the AlInGaP material and having a pn junction, and uses as the bottom cell a solar cell lattice-matched to the top cell, formed with an InGaAsN material and having a pn junction.

FIG. 1 shows a structure of a solar cell according to this aspect. As shown in FIG. 1, a backside electric field layer composed of a p-type InGaP material is formed on a substrate composed of a p-type GaAs material. Then, a base layer composed of a p-type InGaAsN material is formed on the backside electric field layer, and an emitter layer composed of an n-type InGaAsN material is formed on the base layer. Further, a window layer composed of an n-type AlInP material is formed on the emitter layer, an n-type InGaP layer is formed on the window layer, and a p-type AlGaAs layer is formed on the InGaP layer. Tunnel junction is formed between these two layers, that is, the InGaP layer and the AlGaAs layer.

In addition, a backside electric field layer composed of a p-type AlInP material is formed on the AlGaAs layer. A base layer composed of a p-type AlInGaP material is formed on the backside electric field layer, and an emitter layer composed of an n-type AlInGaP material is formed on the base layer. Then, a window layer composed of an n-type AlInP material is formed on the emitter layer, and a cap composed of an n-type GaAs material is formed on the window layer. Here, film thicknesses of the layers described above are as shown in FIG. 1 in a unit of μm. The film thickness of the base layer composed of the p-type AlInGaP material is set to a parameter.

The solar cell with a structure described above can be fabricated with an MOCVD method. More specifically, a GaAs substrate doped with Zn is introduced in a vertical MOCVD apparatus for epitaxial growth. During epitaxial growth, a growth temperature may be set to 700° C., for example. Trimethyl gallium (TMG) and arsine (AsH₃) may be used as a material for growth of the GaAs layer regardless of its conductivity type of n or p.

Trimethyl indium (TMI), trimethyl aluminum (TMA), TMG, and phosphine (PH₃) may be used as a material for epitaxial growth of the AlInGaP layer regardless of its conductivity type of n or p. In addition, TMA, TMI and PH₃ may be used as a material for epitaxial growth of the AlInP layer regardless of its conductivity type of n or p.

In all layers of GaAs, AlInGaP and AlInP described above, monosilane (SiH₄) may be used as an impurity for n-type doping, while DEZn may be used as an impurity for p-type doping.

In forming tunnel junction during above-described epitaxial growth, TMI, TMG and AsH₃ may be used as a material for epitaxial growth of the AlGaAs layer, and carbon tetrabromide (CBr₄) may be used as an impurity for p-type doping. In addition, TMI, TMG and PH₃ may be used as a material for epitaxial growth of the InGaP layer, and diethyl tellurium (DETe) is used as an impurity for n-type doping.

In this manner, in a dual-junction solar cell, a short-circuit current as high as that in the conventional art, in which current-matching has been achieved by adjusting a film thickness, is generated, and the absorption edge wavelength is decreased. Excellent open-circuit voltage can thus be obtained, and conversion efficiency can be improved.

According to a current-matching method in a multijunction solar cell according to another aspect of the present invention, a ratio of an Al composition in an AlInGaP material for a top cell is adjusted in order to achieve matching between photocurrents generated in the top cell and a middle cell in a multijunction solar cell. The multijunction solar cell uses as the top cell a solar cell formed with the AlInGaP material and having a pn junction, uses as the middle cell a solar cell lattice-matched to the top cell, formed with an InGaAsN material and having a pn junction, and uses as a bottom cell a solar cell lattice-matched to the middle cell, formed with a Ge material and having a pn junction.

FIG. 2 shows a structure of a solar cell according to this aspect. As shown in FIG. 2, a buffer layer composed of an n-type InGaAs material is formed on a substrate composed of a p-type Ge material and doped with Ga. Here, As in the n-type InGaAs layer diffuses in the Ge substrate to also form an n-type Ge layer. Then, an n-type InGaP layer is formed on the buffer layer, and a p-type AlGaP layer is formed on the InGaP layer. Tunnel junction is formed between these two layers, that is, the InGaP layer and the AlGaP layer. A backside electric field layer composed of a p-type InGaP material is formed on the AlGaAs layer, and a base layer composed of a p-type InGaAsN material is formed on the backside electric field layer. An emitter layer composed of an n-type InGaAsN material is formed on the base layer, and a window layer composed of an n-type AlInP material is formed on the emitter layer. Further, an n-type InGaP layer is formed on the window layer, and a p-type AlGaAs layer is formed on the InGaP layer. Tunnel junction is formed between these two layers, that is, the n-type InGaP layer and the p-type AlGaAs layer.

In addition, a backside electric field layer composed of a p-type AlInP material is formed on the AlGaAs layer. A base layer composed of a p-type AlInGaP material is formed on the backside electric field layer, and an emitter layer composed of an n-type AlInGaP material is formed on the base layer. Then, a window layer composed of an n-type AlInP material is formed on the emitter layer, and a cap composed of an n-type GaAs material is formed on the window layer. Here, film thicknesses of the layers described above are as shown in FIG. 2, and the film thickness of the base layer composed of the p-type AlInGaP material is set to a parameter.

A method of fabricating a solar cell with this structure and a material for the same may be similar to those for the solar cell described previously.

In this manner, in a triple-junction solar cell, a short-circuit current as high as the same as that in the conventional art, in which current-matching has been achieved by adjusting a film thickness, is generated, and the absorption edge wavelength is decreased. Excellent open-circuit voltage can thus be obtained, and conversion efficiency can be improved.

Preferably, the AlInGaP material for the top cell has a thickness sufficient to attain at least 98% absorption of sunlight having a wavelength equal to or smaller than an absorption edge wavelength. Here, the absorption edge wavelength refers to a wavelength longest among the wavelengths that a solar cell can absorb. More specifically, the following equation is preferably satisfied:

Absorption edge wavelength (nm)=1239.8/Eg(eV)

where Eg (eV) represents band gap energy of the AlInGaP layer. In addition, desirably, lowering of Eg due to ordering of an atom sequence specific to the InGaP-based material is not significant. Here, Eg preferably has a value satisfying the following equation:

Eg=1.88+1.26x

where x represents a ratio of Al composition in group III element in the AlInGaP layer. From the above-described relation, when x=0.05 for example, the absorption edge wavelength is set to 638 nm. Meanwhile, when x=0.15, the absorption edge wavelength is set to 600 nm. In the present invention, preferably, Eg of AlInGaP is within a range from 1.94 to 2.03 eV. Eg should be increased in order to obtain a voltage as high as possible. If Eg is too large, however, a generated current will be too small to achieve current-matching. Therefore, preferably, a material for the top cell has relatively high Eg from 1.97 to 2.03 eV for the space sunlight of which short-wavelength light intensity is high. On the other hand, the material for the top cell preferably has Eg from 1.94 to 1.97 eV for the terrestrial sunlight of which short-wavelength light intensity is not too high.

Preferably, the Al composition ratio in the AlInGaP material is within a range from 0.05 to 0.15, and an N composition ratio in the InGaAsN material is within a range from 0 to 0.03. If the Al composition ratio is lower than 0.05, Eg of the top cell will be too small and a diffusion potential will, also be small, resulting in lower generated voltage. On the other hand, if the Al composition ratio exceeds 0.15, generated current will be too small as compared with that in the cell in the lower portion, resulting in failure in current matching.

According to a multijunction solar cell according to another aspect of the present invention, an Al composition ratio in an AlInGaP material for a top cell is within a range from 0.05 to 0.15 in a multijunction solar cell. The multijunction solar cell uses as the top cell a solar cell formed with the AlInGaP material and having a pn junction, and uses as a bottom cell a solar cell lattice-matched to the top cell, formed with an InGaAsN material and having a pn junction.

According to a multijunction solar cell according to yet another aspect of the present invention, an Al composition ratio in an AlInGaP material for a top cell is within a range from 0.05 to 0.15 in a multijunction solar cell. The multijunction solar cell uses as the top cell a solar cell formed with the AlInGaP material and having a pn junction, uses as a middle cell a solar cell lattice-matched to the top cell, formed with an InGaAsN material and having a pn junction, and uses as a bottom cell a solar cell lattice-matched to the middle cell, formed with a Ge material and having a pn junction.

Preferably, the AlInGaP material for the top cell has a thickness sufficient to attain at least 98% absorption of sunlight having a wavelength equal to or smaller than an absorption edge wavelength. Moreover, preferably, an N composition ratio in the InGaAsN material is within a range from 0 to 0.03.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIGS. 1 and 2 are schematic cross-sectional views showing a structure of a solar cell according to the present invention.

FIG. 3 is a schematic cross-sectional view showing a layered structure of an AlInGaP/InGaAs/Ge triple-junction solar cell according to the present invention.

FIG. 4 is a graph showing a relation of a ratio of Al composition in an AlInGaP layer with photocurrents in the AlInGaP layer and an InGaAs (containing 1% of In) cell below the same, under a condition of AM 1.5.

FIG. 5A is a graph showing a relation of a thickness of InGaP (not containing Al) with conversion efficiency in a conventional art under the condition of AM 1.5.

FIG. 5B is a graph showing a relation of a ratio of Al composition in an AlInGaP cell with conversion efficiency in the present invention under the condition of AM 1.5.

FIG. 6 is a graph showing a relation of a ratio of Al composition in the AlInGaP layer with photocurrents in the AlInGaP layer and the InGaAs (containing 1% of In) cell below the same under the condition of AM 0.

FIG. 7A is a graph showing a relation between a film thickness and conversion efficiency in the AlInGaP/InGaAs/Ge triple-junction solar cell under the condition of AM 0.

FIG. 7B is a graph showing a relation of a ratio of Al composition in the AlInGaP cell with conversion efficiency in the present invention under the condition of AM 0.

FIG. 8 is a graph showing a relation of a ratio of Al composition in the AlInGaP layer with photocurrents in the AlInGaP cell and the InGaAs (containing 1% of In) cell below the same under the condition of AM 0 (after irradiation with radiation).

FIG. 9A is a graph showing a relation between a film thickness and conversion efficiency in the AlInGaP/InGaAs/Ge triple-junction solar cell under the condition of AM 0 (after irradiation with radiation).

FIG. 9B is a graph showing a relation of a ratio of Al composition in the AlInGaP cell with conversion efficiency in the present invention under the condition of AM 0 (after irradiation with radiation).

FIG. 10 is a schematic cross-sectional view showing a structure of an epitaxial layer in a dual-junction solar cell according to the conventional art.

FIG. 11 is a graph showing a relation between a thickness of an InGaP cell and a short-circuit current value in the dual-junction solar cell.

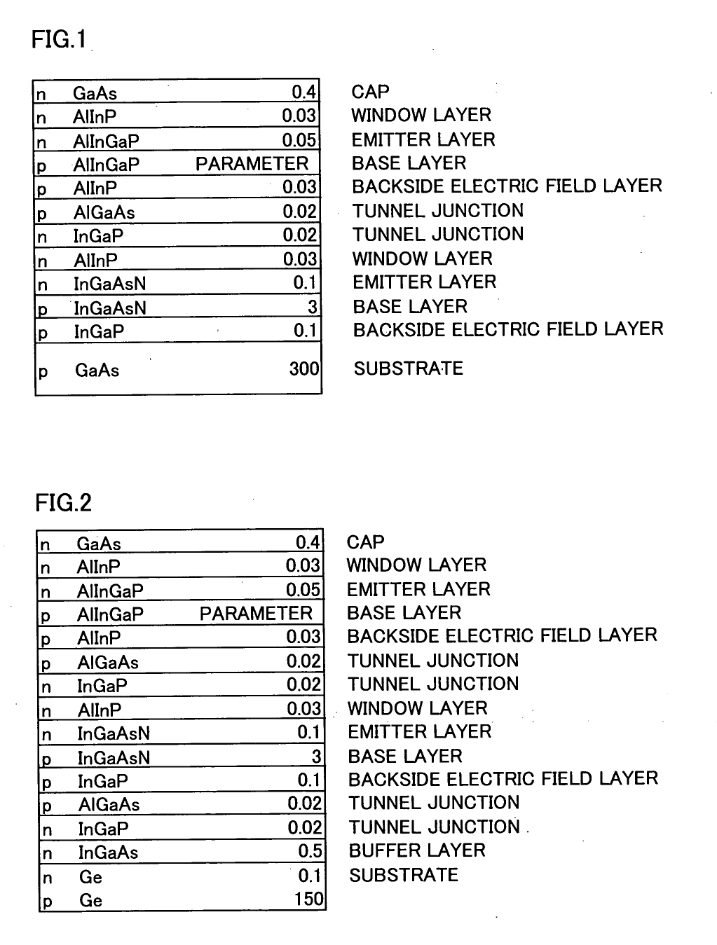

### DESCRIPTION OF THE PREFERRED EMBODIMENTS

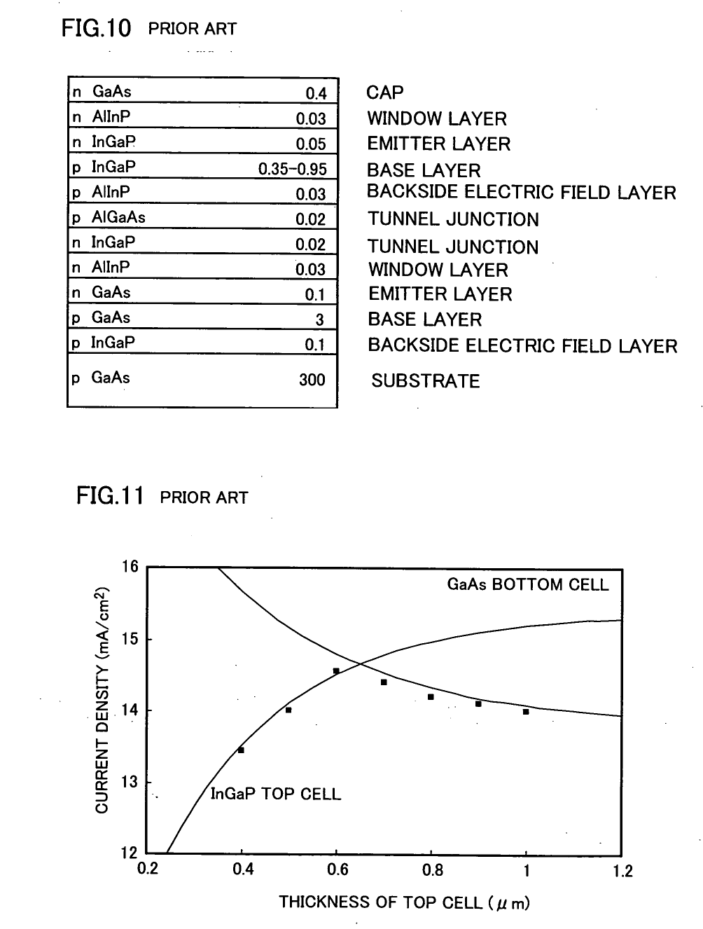

In the present embodiment, for better understanding of the present invention, an InGaP/GaAs dual-junction solar cell and a manufacturing process thereof according to the conventional art will now be described with reference to FIG. 10. Here, FIG. 10 is a schematic cross-sectional view showing a structure of an epitaxial layer in a dual-junction solar cell according to the conventional art.

First, a layered structure is fabricated on a p-type GaAs substrate, using MOCVD method. Namely, a GaAs substrate having a diameter of approximately 50 mm and doped with Zn is introduced in a vertical MOCVD apparatus, and the layered structure as shown in FIG. 10 is epitaxially grown successively. Specifically, a p-type InGaP layer is formed as a backside electric field layer on the p-type GaAs substrate. Then, a p-type GaAs layer is formed as a base layer on the p-type InGaP layer, and an n-type GaAs layer is formed as an emitter layer on the p-type GaAs layer. Further, an n-type AlInP layer is formed as a window layer on the n-type GaAs layer, an n-type-InGaP layer is formed on the n-type AlInP layer, and a p-type AlGaAs layer is formed on the n-type InGaP layer. Tunnel junction is formed between the n-type AlInP layer and the p-type AlGaAs layer.

In addition, a p-type AlInP layer is formed as a backside electric field layer on the p-type AlGaAs layer. A p-type InGaP layer is formed as a base layer on the p-type AlInP layer, and an n-type InGaP layer is formed as an emitter layer on the p-type InGaP layer. Then, an n-type AlInP layer is formed as a window layer on the n-type InGaP layer, and an n-type GaAs layer is formed as a cap layer on the n-type AlInP layer. Here, film thicknesses of the layers described above are as shown in the drawing in a unit of μm.

During epitaxial growth described above, a growth temperature is preferably set to 700° C. Trimethyl gallium (TMG) and arsine (AsH₃) may be used as a material for growth of the GaAs layer regardless of its conductivity type of n or p.

Trimethyl indium (TMI), TMG and phosphine (PH₃) may be used as a material for epitaxial growth of the InGaP layer regardless of its conductivity type of n or p. In addition, trimethyl aluminum (TMA), TMI and PH₃ may be used as a material for epitaxial growth of the AlInP layer regardless of its conductivity type of n or p.

In all layers of GaAs, InGaP and AlInP described above, monosilane (SiH₄) may be used as an impurity for n-type doping, and DEZn may be used as an impurity for p-type doping.

In forming tunnel junction during above-described epitaxial growth, TMI, TMG and AsH₃ may be used as a material for epitaxial growth of the AlGaAs layer, and carbon tetrabromide (CBr₄) may be used as an impurity for p-type doping.

After a solar cell structure is formed through epitaxial growth, a resist is formed with photolithography on a surface substrate of the solar cell structure except for an area where an electrode pattern is formed. Then, the solar cell structure is introduced in a vacuum deposition apparatus, and a layer composed of Au and containing 12% Ge is formed with a resistance heating method on the substrate having the resist formed. The Au layer may have a thickness of approximately 100 nm, for example. Thereafter, an Ni layer and an Au layer are formed on the Au layer in this order with EB deposition to a thickness of approximately 20 nm and approximately 5000 nm respectively. Then, a surface electrode with a desired pattern is obtained with a lift-off method.

Using as a mask the surface electrode formed in the above-described manner, the n-type GaAs cap layer in a portion where the surface electrode has not been formed is etched with an alkaline aqueous solution.

Then, a resist is formed with photolithography on the surface of an epitaxial wafer except for an area for mesa etching pattern. Thereafter, an epitaxial layer in an area where the resist is not formed is etched with an alkaline aqueous solution and an acid-aqueous solution so as to expose the GaAs substrate.

An Ag layer serving as a backside electrode is formed on the backside substrate of the solar cell structure with EB deposition to a thickness of approximately 1000 nm. After the backside electrode is formed, a TiO₂ film and an Al₂O₃ film serving as an antireflection coating are formed in this order on an outermost surface to a thickness of approximately 50 nm and approximately 85 nm respectively.

Thereafter, heat treatment at 380° C. is performed in nitrogen for the purpose of sintering the surface electrode and annealing the backside electrode and the antireflection coating. Then, the solar cell structure is cut into a cell in such a manner that a dicing line falls on a line that has been subjected to mesa etching. The cell may have a size of 10 mm×10 mm, for example.

In order to evaluate the characteristics of the solar cell fabricated in the above-described manner, current and voltage characteristics when the solar cell is irradiated with light are measured with a solar simulator emitting AM 1.5 reference sunlight, whereby a short-circuit current, an open-circuit voltage and conversion efficiency can be measured. Here, the conversion efficiency is calculated in accordance with the following equation:

Conversion efficiency=Open-circuit voltage (V)×Short-circuit current (mA)×FF

where FF represents a fill factor of a solar cell output curve. In the present invention, FF can be set to 0.85.

FIG. 11 shows a short-circuit current value in a dual-junction cell when the thickness of the p-type InGaP base layer is varied from 0.35 to 0.95 μm and the thickness of the InGaP cell is varied from 0.4 to 1 μm in the dual-junction solar cell. In FIG. 11, the ordinate represents current density (mA/cm²) while the abscissa represents the thickness of the top cell (μm). FIG. 4 shows with a solid line a calculation result of values for photocurrents generated in the InGaP top cell and the GaAs bottom cell, using a two-dimensional device simulator. Though the short-circuit current value in the dual-junction cell is restricted to a lower value out of the values for the photocurrents generated in the top cell and the bottom cell, it can be seen that the calculation result by the device simulator is substantially equal to the actually measured value. In addition, as shown in FIG. 11, the short-circuit current attains the highest value when the thickness of the InGaP top cell is set to 0.6 μm. In all InGaP top cells having a thickness different from one another, the open-circuit voltage is substantially the same, and the conversion efficiency is highest when the thickness of the top cell is set to 0.6 μm.

### First Embodiment

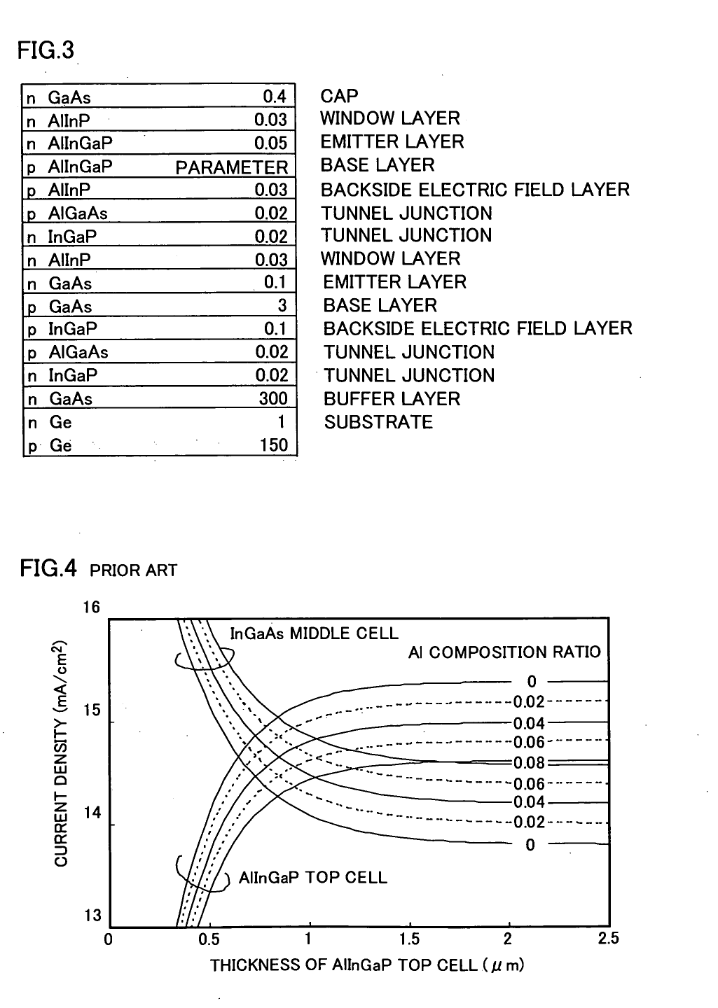

In the first embodiment, a triple-junction solar cell exactly as shown in FIG. 3 is fabricated using a procedure similar to that in the conventional art. FIG. 3 is a schematic cross-sectional view showing a layered structure of an AlInGaP/InGaAs/Ge triple-junction solar cell according to the present invention. A numerical value in the drawing represents a thickness of a layer in a unit of μm.

As shown in FIG. 3, an n-type GaAs layer is formed as a buffer layer on a p-type Ge substrate doped with Ga. Here, As in the n-type GaAs layer diffuses in the Ge substrate to form an n-type Ge layer. Then, an n-type InGaP layer is formed on the n-type GaAs layer, and a p-type AlGaAs layer is formed on the n-type InGaP layer. Tunnel junction is formed between the n-type InGaP layer and the p-type AlGaAs layer.

A p-type InGaP layer is formed as a backside electric field layer on the p-type AlGaAs substrate, and a p-type GaAs layer is formed as a base layer on the p-type InGaP layer. An n-type GaAs layer is formed as an emitter layer on the p-type GaAs layer, and an n-type AlInP layer is formed as a window layer on the n-type GaAs layer. Further, an n-type InGaP layer is formed on the n-type AlInP layer, and a p-type AlGaAs layer is formed on the n-type InGaP layer. Tunnel junction is formed between the n-type InGaP layer and the p-type AlGaAs layer.

In addition, a p-type AlInP layer is formed as a backside electric field layer on the p-type AlGaAs layer. A p-type AlInGaP layer is formed as a base layer on the p-type AlInP layer, and an n-type AlInGaP layer is formed as an emitter layer on the p-type AlInGaP layer. Then, an n-type AlInP layer is formed as a window layer on the n-type AlInGaP layer, and an n-type GaAs layer is formed as a cap layer on the n-type AlInP layer.

The short-circuit current, the open-circuit voltage and the conversion efficiency were examined when the Al composition ratio in the, AlInGaP cell in the triple-junction solar cell with the above-described structure was varied in the first embodiment. The current density was analyzed from calculation by the two-dimensional device simulator. The result is shown in FIG. 4. FIG. 4 is a graph showing photocurrents in the AlInGaP layer and the InGaAs (containing 1% of In) cell below the same when the Al composition ratio in the AlInGaP layer is varied under the condition of AM 1.5. Here, the thickness of the AlInGaP cell base layer was also varied concurrently.

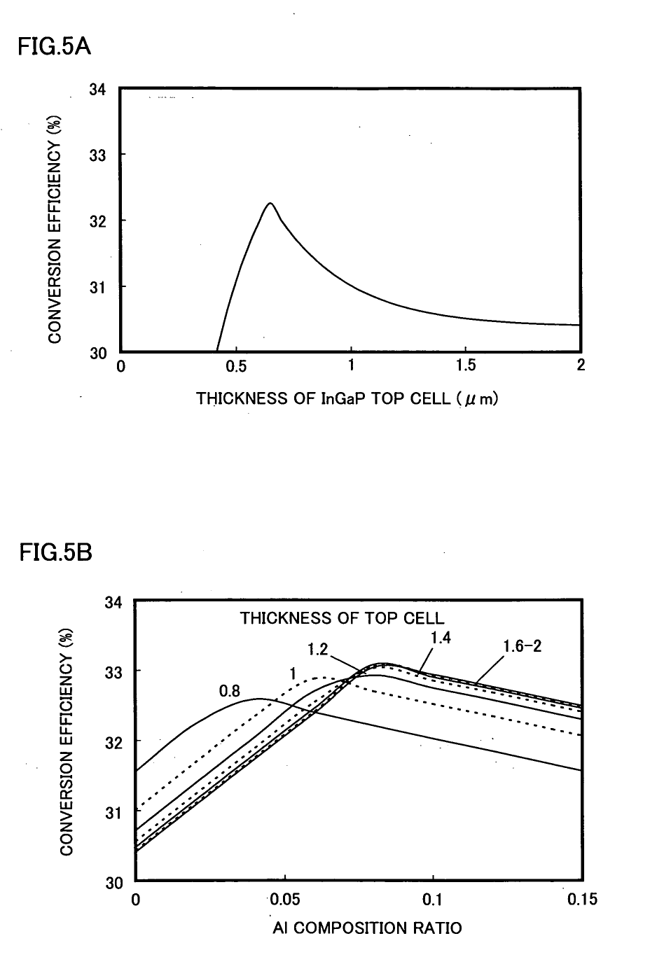

In FIG. 4, an intersection of the photocurrent in the AlInGaP cell with the photocurrent in the InGaAs cell represents a current-matching point. The conversion efficiency in the AlInGaP/InGaAs/Ge triple,junction solar cell was calculated based on the result shown in FIG. 4. FIG. 5A shows conversion efficiency achieved according to the conventional art in which the thickness of InGaP (not containing Al) is varied, while FIG. 5B shows conversion efficiency achieved according to the present invention when the Al composition ratio in the AlInGaP cell is varied. It is noted that FIG. 5B shows results with regard to respective film thicknesses of the AlInGaP layer varied from 0.8 to 2 μm.

As shown in FIG. 5B, conversion efficiency when the thickness of the AlInGaP cell was set to not smaller than 0.8 μm in the first embodiment was calculated. As a result, conversion efficiency higher than that achieved according to the conventional art was obtained when the Al composition ratio was set to be within a range from 0.05 to 0.15, as shown in FIG. 5B.

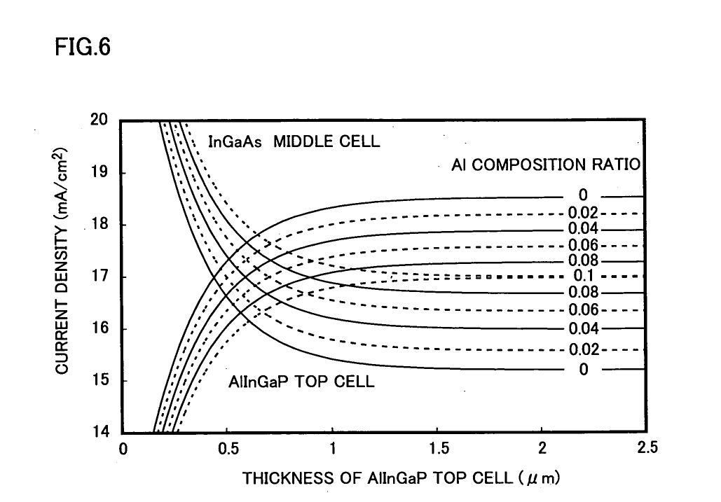

Similar examination was also performed under the condition of AM 0. FIG. 6 is a graph showing the current density in the AlInGaP layer and the InGaAs (containing 1% of In) cell below the same when the Al composition ratio in the AlInGaP layer is varied in the structure shown in FIG. 3. Here, the thickness of the AlInGaP cell base layer was also varied concurrently.

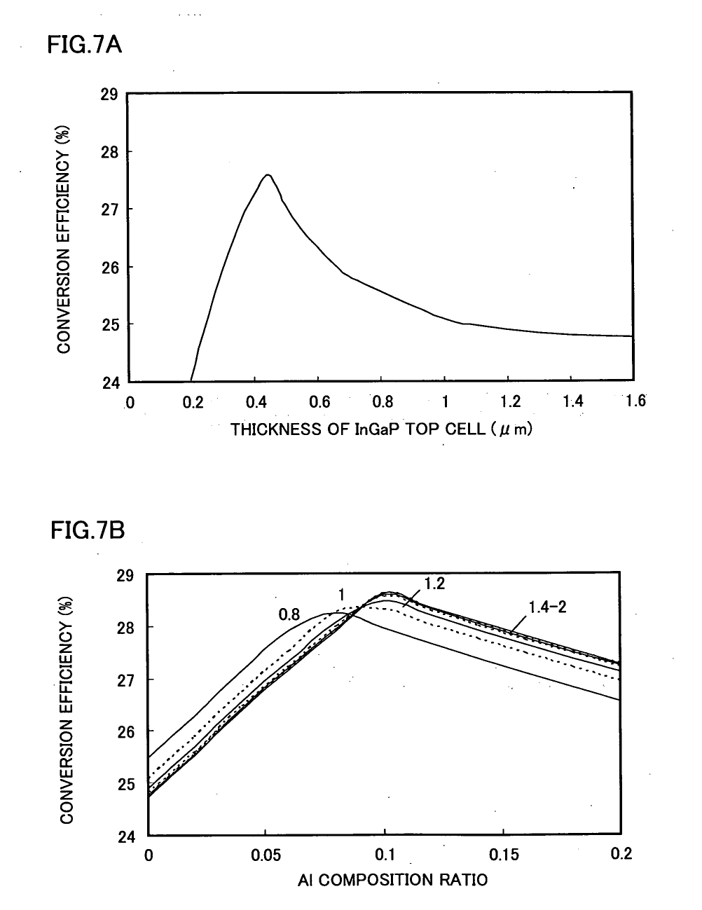

In FIG. 6, an intersection of the photocurrent in the AlInGaP cell with the photocurrent in the InGaAs cell represents a current-matching point. The conversion efficiency in the AlInGaP/InGaAs/Ge triple-junction solar cell was calculated based on the result shown in FIG. 6. FIG. 7A shows conversion efficiency achieved according to the conventional art in which the thickness of InGaP (not containing Al) is varied, while FIG. 7B shows conversion efficiency achieved according to the present invention when the Al composition ratio in the AlInGaP cell is varied. It is noted that FIG. 7B shows results with regard to the film thicknesses of the AlInGaP layer varied from 0.8 to 2 μm.

As shown in FIG. 7B, conversion efficiency when the thickness of the AlInGaP cell was set to not smaller than 0.8 μm in the first embodiment was calculated. As a result, conversion efficiency higher than that achieved according to the conventional art was obtained when the Al composition ratio was set to be within a range from 0.05 to 0.15.

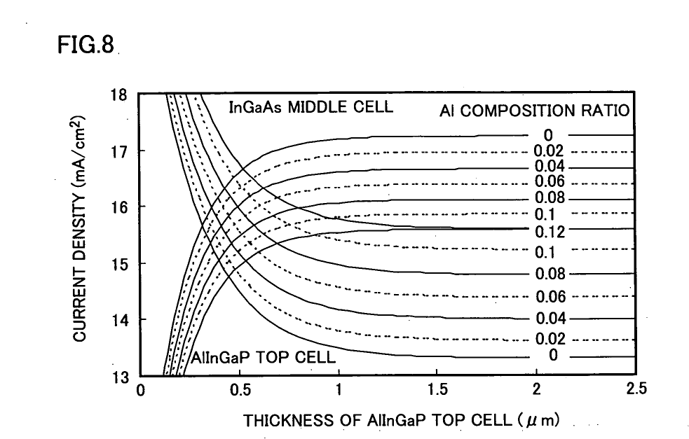

In addition, a variety of characteristics of the triple-junction solar cell fabricated in the first embodiment were measured in a similar manner, also under the condition of AM 0 spectrum after the solar cell is irradiated with electron beam of 1e¹⁵/cm², which is comparable to total radiation received on a stationary orbit in space for a time period of one year. FIG. 8 shows a calculation result of the current density in the AlInGaP cell and the InGaAs (containing 1% of In) cell below the same when the Al composition ratio is varied in the AlInGaP layer in the structure shown in FIG. 3.

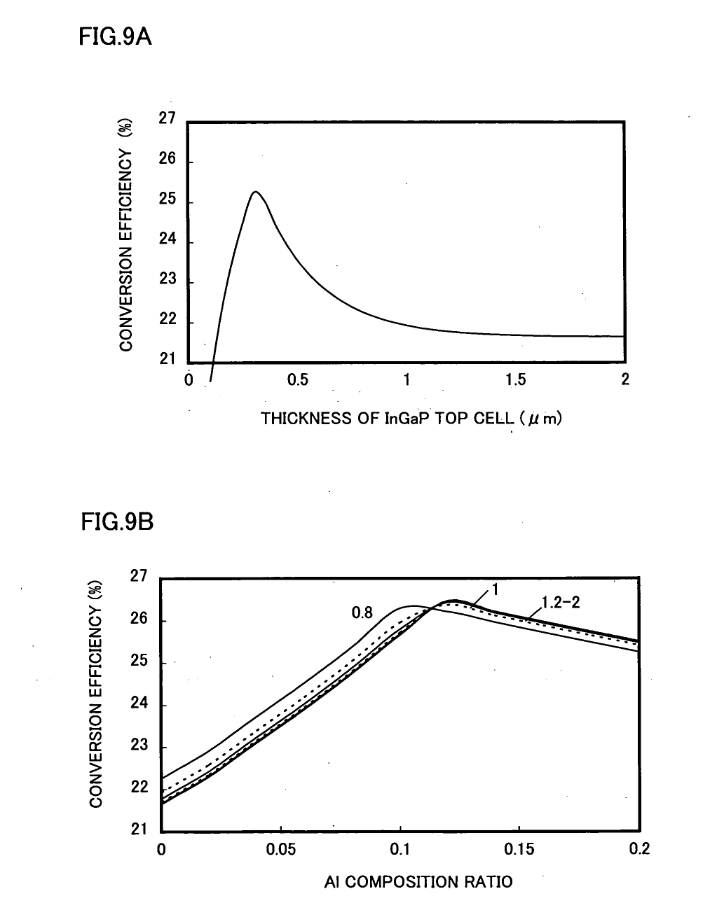

It can be seen from comparison of FIG. 4 with FIG. 8 that the thickness of the GaAs cell is smaller than that of the current-matched AlInGaP cell base layer, because the current value is lowered more significantly in the GaAs cell after the solar cell is irradiated with radiation. Based on the calculation result shown in FIG. 8, conversion efficiency of the AlInGaP/InGaAs/Ge triple-junction solar cell and conversion efficiency achieved when the Al composition ratio in the present invention is varied are shown in FIGS. 9A and 9B respectively.

As shown in FIG. 9B, conversion efficiency when the thickness of the AlInGaP cell was set to not smaller than 0.8 μm in-the first embodiment was calculated. As a result, conversion efficiency higher than that achieved according to the conventional art was obtained when the Al composition ratio was set to be within a range from 0.05 to 0.15.

### Second Embodiment

A single-junction cell formed with the AlInGaP material was fabricated on the p-type GaAs substrate, using the procedure described in the previous embodiment. Specifically, a p-type AlGaAs layer is formed as a tunnel junction on the p-type GaAs substrate, and a p-type AlInP layer is formed as a backside electric field layer on the AlGaAs layer. Then, a p-type AlInGaP layer is formed as a base layer on the p-type AlInP layer, and an n-type AlInGaP layer is formed as an emitter layer on the p-type AlInGaP layer. Further, an n-type AlInP layer is formed as a window layer on the n-type AlInGaP layer, and an n-type GaAs layer is formed as a cap layer on the n-type AlInP layer.

The single-junction cell described above is implemented as a solar cell through process steps the same as those in the previous embodiment, except for obtaining the layered structure described above.

In the single-junction cell with the above-described structure, the Al composition ratio in the AlInGaP layer was varied from 0.07 to 0.14. In addition, the AlInGaP layer had a lattice constant matched to that of the GaAs substrate in such a manner that the following equation was satisfied.

(Al+Ga):In=0.52:0.48

Moreover, the thickness of the p-type AlInGaP base layer was also varied from 0.55 to 2.45 μm, while the thickness of the AlInGaP cell was varied from 0.6 to 2.5 μm. Table 1 shows a result of examination of the photocurrent.

TABLE 1

| | | | Open- | Short- | | |
|---|---|---|---|---|---|---|
| | Al com- | Cell | circuit | circuit | | Conversion |
| | position | thickness | voltage | current | | efficiency |
| Material | ratio | (μm) | (V) | (mA) | FF | (%) |
| AlInGaP | 0.14 | 0.6 | 1.504 | 7.05 | 0.857 | 9.1 |
| | 0.12 | 1 | 1.499 | 8.41 | 0.835 | 10.53 |
| | 0.13 | 2 | 1.523 | 8.59 | 0.847 | 11.09 |
| | 0.07 | 1.5 | 1.467 | 9.7 | 0.856 | 12.18 |
| | 0.07 | 2 | 1.491 | 9.97 | 0.853 | 12.67 |
| | 0.07 | 2.5 | 1.481 | 10.05 | 0.857 | 12.75 |
| InGaP | 0 | 0.6 | 1.39 | 10.1 | 0.857 | 12.03 |

As can be seen from the result shown in Table 1, in the AlInGaP cell having the Al composition ratio of 0.07 and the cell thickness of 2 to 2.5 μm, the short-circuit current (Isc) equivalent to that of the conventional InGaP cell without containing Al (Al composition ratio is 0) was obtained. In addition, high open-circuit voltage of 90 to 100 mV was obtained.

Table 2 shows comparison of characteristics between an AlInGaP/GaAs tandem cell fabricated with the -AlInGaP top cell having the Al composition ratio of 0.07 and the cell thickness of 2.5 μm and an InGaP/GaAs tandem cell using the conventional InGaP top cell.

TABLE 2

| | | Open- | | | |
|---|---|---|---|---|---|
| | | circuit | Short-circuit | | Conversion |
| | | voltage | current | | efficiency |
| | | (V) | (mA) | FF | (%) |
| Conventional | InGaP/GaAs | 2.45 | 14.1 | 0.857 | 29.6 |
| Example | | | | | |
| Present | AlInGaP/ | 2.54 | 14 | 0.856 | 30.5 |
| Invention | GaAs | | | | |

As can be seen from the result shown in Table 2, with the use of AlInGaP top cell, the open-circuit voltage can be improved and the conversion efficiency can be increased by approximately 1% without lowering the short-circuit current.

As shown in the embodiments above, according to the current-matching method of the present invention, the conversion efficiency of the AlInGaP/InGaAs/Ge triple-junction cell has been enhanced, as compared with the conventional current-matching method. Specifically, as compared with the conventional example, the conversion efficiency has been improved to approximately 1.026 times under the condition of AM 1.5, to approximately 1.037 times under the condition of AM 0 (before irradiation with radiation), and to approximately 1.047 times under the condition of AM 0 (after irradiation with radiation).

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A current-matching method in a multijunction solar cell, characterized in that a ratio of an Al composition in an AlInGaP material for a top cell is adjusted in order to achieve matching between photocurrents generated in the top cell and a bottom cell in a multijunction solar cell, the multijunction solar cell using as the top cell a solar cell formed with the AlInGaP material and having a pn junction, and using as the bottom cell a solar cell lattice-matched to the top cell, formed with an InGaAsN material and having a pn junction.

2. The current-matching method in a multijunction solar cell according to claim 1, characterized in that said AlInGaP material for said top cell has a thickness sufficient to attain at least 98% absorption of sunlight having a wavelength equal to or smaller than an absorption edge wavelength.

3. The current-matching method in a multijunction solar cell according to claim 1, characterized in that said Al composition ratio in group III element is in the AlInGaP material within a range from 0.05 to 0.15.

4. A current-matching method in a multijunction solar cell, characterized in that a ratio of an Al composition in an AlInGaP material for a top cell is adjusted in order to achieve matching between photocurrents generated in the top cell and a middle cell in a multijunction solar cell, the multijunction solar cell using as the top cell a solar cell formed with the AlInGaP material and having a pn junction, using as the middle cell a solar cell lattice-matched to the top cell, formed with an InGaAsN material and having a pn junction, and using as a bottom cell a solar cell lattice-matched to the middle cell, formed with a Ge material, and having a pn junction.

5. The current-matching method in a multijunction solar cell according to claim 4, characterized in that said AlInGaP material for said top cell has a thickness sufficient to attain at least 98% absorption of sunlight having a wavelength equal to or smaller than an absorption edge wavelength.

6. The current-matching method in a multijunction solar cell according to claim 4, characterized in that said Al composition ratio in group III element in the AlInGaP material is within a range from 0.05 to 0.15.

7. The current-matching method in a multijunction solar cell according to claim 4, characterized in that an N composition ratio in group V element in said InGaAsN material is within a range from 0 to 0.03.

8. A multijunction solar cell, characterized in that an Al composition ratio in group III element in an AlInGaP material for a top cell is within a range from 0.05 to 0.15 in a multijunction solar cell, the multijunction solar cell using as the top cell a solar cell formed with the AlInGaP material and having a pn junction, and using as a bottom cell a solar cell lattice-matched to the top cell, formed with an InGaAsN material and having a pn junction.

9. The multijunction solar cell according to claim 8, characterized in that said top cell has a thickness sufficient to attain at least 98% absorption of sunlight having a wavelength equal to or smaller than an absorption edge wavelength.

10. A multijunction solar cell, characterized in that an Al composition ratio in group III element in an AlInGaP material for a top cell is within a range from 0.05 to 0.15 in a multijunction solar cell, the multijunction solar cell using as the top cell a solar cell formed with the AlInGaP material and having a pn junction, using as a middle cell a solar cell lattice-matched to the top cell, formed with an InGaAsN material and having a pn junction, and using as a bottom cell a solar cell lattice-matched to the middle cell, formed with a Ge material and having a pn junction.

11. The multijunction solar cell according to claim 10, characterized in that said top cell has a thickness sufficient to attain at least 98% absorption of sunlight having a wavelength equal to or smaller than an absorption edge wavelength.

12. The multijunction solar cell according to claim 10, characterized in that an N composition ratio in group V element in said InGaAsN material is within a range from 0 to 0.03.
